(19) United States
(12) Patent Application Publication
(10) Pub. No.: US 2024/0301555 A1
(43) Pub. Date: Sep. 12, 2024

(54) SUBSTRATE PROCESSING APPARATUS AND SUBSTRATE PROCESSING METHOD

(71) Applicant: Tokyo Electron Limited, Tokyo (JP)

(72) Inventor: Tatsuya YAMAGUCHI, Tokyo (JP)

(21) Appl. No.: 18/589,845

(22) Filed: Feb. 28, 2024

(30) Foreign Application Priority Data
Mar. 7, 2023 (JP) 2023-034492

(51) Int. Cl. C23C 16/46; C23C 16/455; C23C 16/52; H01L 21/324; H01L 21/67

(52) U.S. Cl. CPC C23C 16/46; C23C 16/45563; C23C 16/52; H01L 21/324; H01L 21/67109

(57) ABSTRACT

A substrate processing apparatus includes a processing container that accommodates a plurality of substrates in an inside thereof to perform a substrate processing on the plurality of substrates, a gas supply nozzle that supplies a gas to the inside of the processing container, and an external heater that heats the plurality of substrates from an outside of the processing container. The substrate processing apparatus further includes an internal heater that is provided independently of the gas supply nozzle in the inside of the processing container and extends at a lateral side of the plurality of substrates in a direction in which the plurality of substrates are arranged to heat the plurality of substrates.

### CROSS-REFERENCE TO RELATED APPLICATIONS

The present application is based on and claims priority from Japanese Patent Application No. 2023-034492, filed on Mar. 7, 2023, with the Japan Patent Office, the disclosure of which is incorporated herein in its entirety by reference.

### TECHNICAL FIELD

The present disclosure relates to a substrate processing apparatus and a substrate processing method.

### BACKGROUND

Japanese Patent Application Laid-Open No. 2007-081365 discloses a substrate processing apparatus (heat treatment apparatus) in which a plurality of substrates (semiconductor wafers) are accommodated in the inside of a processing container and are heated with a heater provided at the outside of the processing container, thereby subjecting each substrate to substrate processing. The substrate processing apparatus further includes a pre-heating heater provided in the inside of a gas supply nozzle that supplies a processing gas to heat the processing gas before the processing gas is discharged.

Japanese Patent Application Laid-Open No. 2003-324045 discloses a substrate processing apparatus (heat treatment apparatus) that does not include a heater at the outside of a processing container, but the processing apparatus utilizes a heater provided in the inside of the processing container to heat a plurality of substrates.

### SUMMARY

According to an aspect of the present disclosure, there is provided a substrate processing apparatus including a processing container that accommodates a plurality of substrates in an inside thereof to perform a substrate processing on the plurality of substrates, a gas supply nozzle that supplies a gas to the inside of the processing container, and an external heater that heats the plurality of substrates from an outside of the processing container, wherein the substrate processing apparatus further includes an internal heater that is provided independently of the gas supply nozzle in the inside of the processing container and extends at a lateral side of the plurality of substrates in a direction in which the plurality of substrates are arranged to heat the plurality of substrates.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view schematically illustrating a substrate processing apparatus according to the present embodiment.

FIG. 2 is a cross-sectional view of a processing container and a temperature regulation furnace taken along the horizontal direction.

FIG. 3 is a perspective view illustrating an internal heater provided within the processing container.

FIG. 4A is a timing chart illustrating a substrate processing method of the substrate processing apparatus according to the embodiment. FIG. 4B is a timing chart illustrating a substrate processing method of a substrate processing apparatus according to a reference example.

FIG. 5A is a cross-sectional view illustrating the installation form of the internal heater according to a first modification. FIG. 5B is a cross-sectional view illustrating the installation form of the internal heater according to a second modification. FIG. 5C is a cross-sectional view illustrating the installation form of the internal heater according to a third modification.

FIG. 6A is a cross-sectional view illustrating the installation form of the internal heater according to a fourth modification. FIG. 6B is a cross-sectional view illustrating the installation form of the internal heater according to a fifth modification.

### DETAILED DESCRIPTION

The foregoing summary is illustrative only and is not intended to be in any way limiting. In addition to the illustrative aspects, embodiments, and features described above, further aspects, embodiments, and features will become apparent by reference to the drawings and the following detailed description.

Hereinafter, embodiments for carrying out the present disclosure will be described with reference to the drawings. In each drawing, the same reference numerals may be given to the same components, and redundant descriptions may be omitted.

### [Configuration of Substrate Processing Apparatus 1]

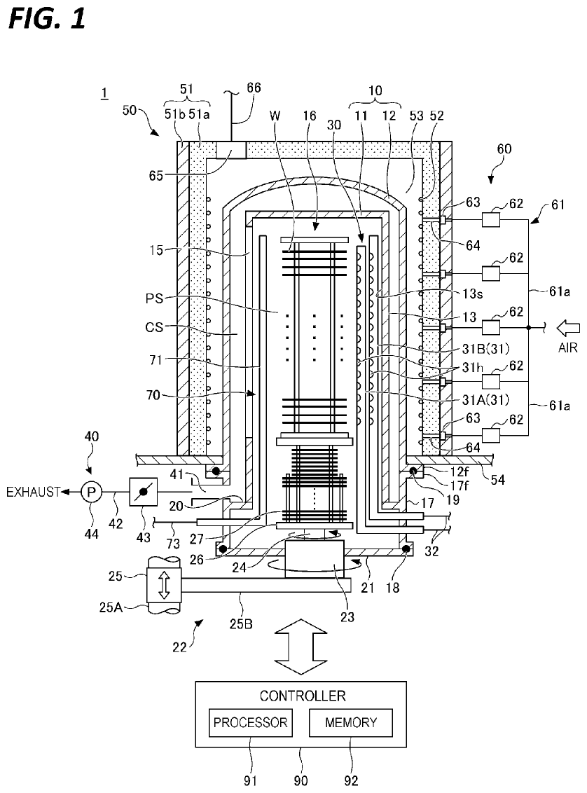

FIG. 1 is a cross-sectional view schematically illustrating a substrate processing apparatus 1 according to an embodiment. The substrate processing apparatus 1 is configured as a vertical film forming apparatus (heat treatment apparatus) that holds a plurality of substrates W side by side in the vertical direction within a processing container 10 and forms a desired film on a surface of each substrate W by atomic layer deposition (ALD), chemical vapor deposition (CVD), thermal oxidation, and other methods. The substrate W, subjected to film formation, is not particularly limited, and may be, for example, a semiconductor substrate such as a silicon wafer or compound semiconductor wafer, or a glass substrate.

The substrate processing apparatus 1 includes a processing container 10 inside which each substrate W is accommodated and subjected to substrate processing, a gas supply 30 that supplies gases into the processing container 10, a gas exhauster 40 that discharges the gases from the processing container 10, and a temperature regulation furnace 50 arranged around the processing container 10. Further, the substrate processing apparatus 1 includes a controller 90 that controls each component of the substrate processing apparatus 1.

The processing container 10 is formed in a cylindrical shape and is installed such that the axis thereof is along the vertical direction (up-and-down direction). Further, the processing container 10 has a double-cylinder structure including an inner cylinder 11 accommodating each substrate W and an outer cylinder 12 accommodating the inner cylinder 11. The inner and outer cylinders 11 and 12 are made of a heat-resistant material such as quartz and are arranged coaxially with each other. The processing container 10 is not limited to the double-cylinder structure, and may also have a single-cylinder structure or a structure composed of three or more cylinders.

The inner cylinder 11 has an open lower end and is provided with a ceiling wall at an upper end thereof. Further, the inner cylinder 11 has an inner diameter larger than the diameter of each substrate W, and also has an axial length longer than the vertical arrangement range of each substrate W. The inside of the inner cylinder 11 serves as a processing space (first space) PS in which gases are supplied to each accommodated substrate W to perform film formation thereon. The inner cylinder 11 is provided at a circumferential position with an opening 15 to allow the gases to flow out from the processing space PS to a circulation space (second space) CS between the inner cylinder 11 and the outer cylinder 12. For example, the vertical length of the opening 15 is set to be equal to or greater than the arrangement range of each substrate W. The position where the opening 15 is formed is not particularly limited, and for example, the opening 15 may be formed in the ceiling wall of the inner cylinder 11.

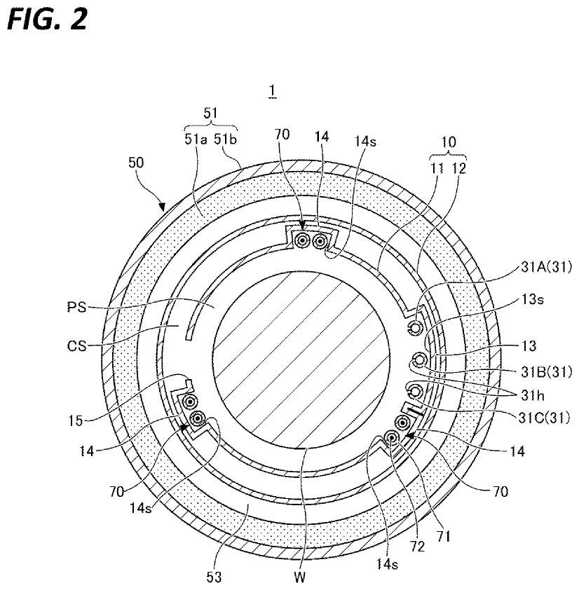

Further, the inner cylinder 11 is provided at a circumferential position opposite to the opening 15 (opposite position across the axis of the inner cylinder 11) with a nozzle accommodating space 13s, which communicates with the processing space PS and is capable of accommodating a gas supply nozzle 31 of the gas supply 30. The nozzle accommodating space 13s is provided inside a nozzle protrusion 13, which protrudes radially outward from a portion of a sidewall of the inner cylinder 11 (see also FIG. 2). The nozzle accommodating space 13s extends parallel to the axis (vertical direction) of the inner cylinder 11.

The outer cylinder 12 has an inner diameter larger than that of the inner cylinder 11 and covers the inner cylinder 11 in a non-contact manner. The circulation space CS formed inside the outer cylinder 12 is continuous to the upper and lateral sides of the inner cylinder 11, and allows the gases moved from the opening 15 to circulate vertically downward.

A lower end of the processing container 10 is supported by a cylindrical manifold 17 made of stainless steel. The manifold 17 has a manifold-side flange 17f at an upper end thereof. The manifold-side flange 17f anchors and supports an outer cylinder-side flange 12f formed at a lower end of the outer cylinder 12. A seal member 19 is sandwiched between the outer cylinder-side flange 12f and the manifold-side flange 17f to airtightly seal the outer cylinder 12 and the manifold 17. Further, the manifold 17 includes an annular support plate 20 on an upper inner wall thereof. The support plate 20 protrudes radially inward from the inner wall to anchor and support the lower end of the inner cylinder 11.

A lid 21 of a substrate placement unit 22 is removably arranged in a lower end opening of the manifold 17. The manifold 17 is provided at a lower end thereof with a seal member 18, which comes into contact with the lid 21 to airtightly block the lower end opening of the manifold 17.

The substrate placement unit 22 includes a wafer boat 16 extending in the vertical direction to protrude upward from the lid 21. The wafer boat 16 includes a plurality of shelves (not illustrated) along the vertical direction, and each shelf holds the outer edge of each substrate W. In a state where the substrates W are held respectively by the wafer boat 16, the substrates W are arranged at a constant interval along the vertical direction and are supported horizontally with respect to each other.

Furthermore, in addition to the wafer boat 16 and the lid 21, the substrate placement unit 22 includes a rotator 23 for rotatably supporting the wafer boat 16, a lifter 25, and a thermal-insulating structure 27.

The rotator 23 is located at the center of the lid 21, and includes a rotation source (not illustrated), a rotating shaft 24 rotated by the rotation source, and a rotating plate 26 connected to an upper end of the rotating shaft 24. The wafer boat 16 is mounted on an upper surface of the rotating plate 26 via the thermal-insulating structure 27. The rotating shaft 24 and the rotating plate 26 rotate the thermal-insulating structure 27 and the wafer boat 16 around the rotational axis under the rotation of the rotator 23.

The lifter 25 includes a column 25A extending in the vertical direction, an arm 25B capable of being raised or lowered relative to the column 25A, and a lifting drive (not illustrated) for raising or lowering the arm 25B. The arm 25B extends substantially horizontally, and supports members (wafer boat 16, rotating plate 26, and thermal-insulating structure 27) above the lid 21, rotator 23, and rotating shaft 24. In the substrate processing apparatus 1, the arm 25B of the lifter 25 is raised or lowered, so that the members above the lid 21, rotator 23, and rotating shaft 24 are integrally moved up and down, enabling the insertion or removal of the wafer boat 16 into or from the processing container 10.

The gas supply 30 includes one or more gas supply nozzles 31 to supply gases to each substrate W within the processing space PS of the processing container 10. Examples of the gases supplied by the gas supply 30 may include processing gases applied to film formation (substrate processing) and a purge gas for purging the processing space PS. Further, the processing gases may include a raw material gas for depositing a precursor on the substrate W and a reaction gas for reacting with the precursor adhered to the substrate W.

FIG. 2 is a cross-sectional view of the processing container 10 and the temperature regulation furnace 50 taken along the horizontal direction. As illustrated in FIG. 2, the gas supply 30 includes three gas supply nozzles 31 (first gas supply nozzle 31A, second gas supply nozzle 31B, and third gas supply nozzle 31C). In FIG. 1, for the convenience of illustration, the first gas supply nozzle 31A and the second gas supply nozzle 31B are illustrated, while the third gas supply nozzle 31C is omitted.

The first gas supply nozzle 31A serves to supply the raw material gas into the processing container 10. The second gas supply nozzle 31B serves to supply the reaction gas into the processing container 10. The third gas supply nozzle 31B serves to supply the purge gas into the processing container 10. The gas supply 30 is not limited to this configuration, and may be configured, for example, to have one or two gas supply nozzles 31 or to have four or more gas supply nozzles 31 by supplying multiple types of gases from the same gas supply nozzle 31.

The first gas supply nozzle 31A to the third gas supply nozzle 31C are injector tubes made of quartz and are arranged side by side in the circumferential direction inside the nozzle protrusion 13 (in the nozzle accommodating space 13s). Each of the first gas supply nozzle 31A to the third gas supply nozzle 31C has a gas hole 31h facing the substrate W accommodated in the processing space PS, and discharges the gas circulated through an internal flow path thereof toward the substrate W. In FIG. 2, the first gas supply nozzle 31A to the third gas supply nozzle 31C are illustrated in order from top to bottom, but the arrangement order of the first gas supply nozzle 31A to the third gas supply nozzle 31C may be designed arbitrarily.

As illustrated in FIG. 1, each gas supply nozzle 31 is fixed to the manifold 17. Further, each gas supply nozzle 31 extends vertically in the inside of the inner cylinder 11 and is bent into an L-shape at a lower end thereof to penetrate the manifold 17 from inside to outside. Each gas supply nozzle 31 has a plurality of gas holes 31h described above at the same interval as the interval between the respective substrates W supported by the wafer boat 16 in the vertical direction. Further, the vertical position of each gas hole 31h is set to be located in the middle between the vertically adjacent substrates W. Each gas hole 31h configured in this way is adapted to discharge the gas in the horizontal direction, thus enabling smooth gas supply to a gap between the respective substrates W.

The gas supply 30 includes a plurality of gas supply paths 32, which are connected respectively to the first gas supply nozzle 31A to the third gas supply nozzle 31C, at the outside of the processing container 10. The gas supply path 32 connected to the first gas supply nozzle 31A is connected to a raw material gas source (not illustrated). The gas supply path 32 connected to the second gas supply nozzle 31B is connected to a reaction gas source (not illustrated). The gas supply path 32 connected to the third gas supply nozzle 31C is connected to a purge gas source (not illustrated). Further, each gas supply path 32 is provided at intermediate positions thereof leading to each gas source with, for example, a flow rate adjuster for adjusting the flow rate of the gas and a valve for opening or closing a flow path in the path (both not illustrated).

The gas exhauster 40 discharges the gases within the processing container 10 to the outside. The gas supplied by each gas supply nozzle 31 moves from the processing space PS of the inner cylinder 11 to the circulation space CS and is then discharged through a gas outlet 41. The gas outlet 41 is formed in an upper sidewall of the manifold 17 above the support plate 20. An exhaust path 42 of the gas exhauster 40 is connected to the gas outlet 41. The gas exhauster 40 is provided with a pressure adjustment valve 43 and a vacuum pump 44 in order from upstream to downstream of the exhaust path 42. The gas exhauster 40 suctions the gases within the processing container 10 using the vacuum pump 44 and adjusts the flow rate of gases to be discharged using the pressure adjustment valve 43, thereby adjusting the internal pressure of the processing container 10.

Then, the substrate processing apparatus 1 according to the embodiment includes a plurality of internal heaters (internal heating elements) 70 that heat each substrate W in the inside of the processing container 10. Each internal heater 70 is positioned laterally adjacent to each substrate W held within the processing container 10. Further, each internal heater 70 is formed to extend linearly between a position higher than the uppermost substrate W and a position lower than the lowermost substrate W among the plurality of substrates W held within the processing container 10. In other words, each internal heater 70 is provided parallel to each gas supply nozzle 31 and extends linearly between a position higher than the uppermost gas hole 31h and a position lower than the lowermost gas hole 31h.

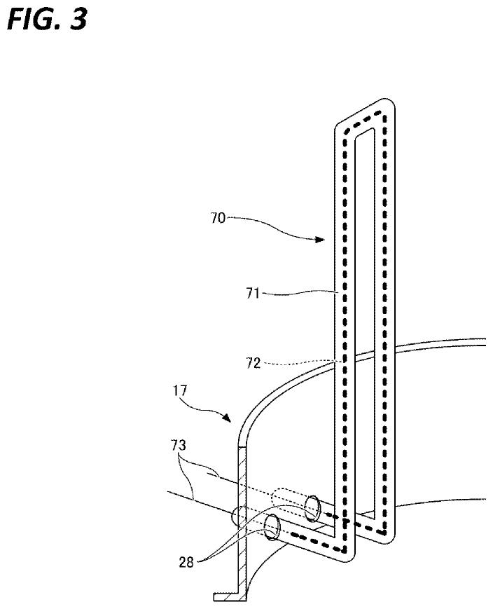

FIG. 3 is a perspective view illustrating the internal heater 70 provided within the processing container 10. As illustrated in FIG. 3, the internal heater 70 includes a hollow tubular member 71 and a heater wire 72 inserted to pass through the inside of the tubular member 71.

The tubular member 71 is made of, for example, quartz. The tubular member 71 is formed into a pair of linearly extending continuous tubes by folding back on the vertical upper side, and is bent into an L-shape on the vertical lower side, thereby being exposed to the outside of the manifold 17. The manifold 17 has a pair of holes 28 to allow the internal heater 70 to pass therethrough. The spacing between the edge of the manifold 17 forming each hole 28 and an outer peripheral surface of the tubular member 71 is closed in an airtight manner by a seal member (not illustrated).

The heater wire 72 is accommodated in the entire vertically extending portion of the tubular member 71 and is connected to a pair of electrical wires 73, which are inserted from the outside into respective bent portions of the tubular member 71. The heater wire 72 is capable of heating the entire vertical direction of the internal heater 70 upon receiving power supplied from a heating driver (not illustrated) through the electrical wires 73. The heater wire 72 is not limited to a linear shape and may have a wiring shape such as a spiral or meandering shape. For example, a carbon wire heater containing carbon may be applied as this type of heater wire 72. The internal heater 70 is not particularly limited in terms of a heating method, and may be, for example, a halogen heater or sheath heater.

As illustrated in FIG. 2, the internal heater 70 according to the embodiment is located inside the inner cylinder 11, and is configured without intervening components between the internal heater 70 and each substrate W accommodated in the processing space PS. Further, three internal heaters 70 are arranged at substantially equal intervals along the circumferential direction of the inner cylinder 11. For example, one of the multiple internal heaters 70 is positioned adjacent to each gas supply nozzle 31 (nozzle protrusion 13). Further, for example, another one of the multiple internal heaters 70 is positioned adjacent to the opening 15.

The processing container 10 includes a plurality of (three) heater protrusions 14 for positioning the internal heaters 70 inside the inner cylinder 11. Similar to the nozzle protrusion 13, the heater protrusion 14 protrudes radially outward at a short distance from the circumferential position of the inner cylinder 11 and extends parallel to the axis (vertical direction) of the inner cylinder 11. The inside of the heater protrusion 14 serves as a heater accommodating space 14s capable of accommodating the pair of continuous tubes of the internal heater 70.

Each internal heater 70 is accommodated in each heater accommodating space 14s, allowing it to be in non-contact with the substrate W accommodated within the processing container 10, but be in sufficiently close to the substrate W (e.g., at a distance of approximately 5 mm to 5 cm). Further, the respective internal heaters 70 are arranged at substantially equal intervals in the circumferential direction and extend between the uppermost substate W and the lowermost substrate W in the vertical direction. The substrate processing apparatus 1 may stably heat all the substrates W using each of these internal heaters 70. The temperature during heating of each internal heater 70 depends on the nature of substrate processing, but may be set slightly higher (e.g., approximately 1 to 1.5 times higher) than a target temperature during substrate processing. For example, when the target temperature of the substrate W during substrate processing is 500° C., the substrate processing apparatus 1 sets the temperature of the internal heater 70 to 600° C. at the start of substrate processing to heat the substrate W. This allows the substrate processing apparatus 1 to significantly shorten the time required to raise the temperature of the substrate W.

Further, the processing container 10 may include a temperature sensor (not illustrated) that detects the temperature of each of a plurality of zones set in the vertical direction within the processing container 10 (e.g., in the processing space PS within the inner cylinder 11). The controller 90 may control the temperature of each internal heater 70 based on temperature information detected by the temperature sensor.

Returning to FIG. 1, the temperature regulation furnace 50 encloses the entire processing container 10 and heats and cools each substrate W accommodated in the processing container 10 from the outside. Specifically, the temperature regulation furnace 50 includes a cylindrical housing 51 with a ceiling and an external heater 52 provided inside the housing 51.

The housing 51 is attached to an upper surface of a base plate 54, which is located at the boundary between the processing container 10 and the manifold 17, to enable the heating of the processing container 10 accommodated therein. The housing 51 is spaced apart from the processing container 10, thus forming a temperature regulation space 53 between the processing container 10 and the housing 51.

The housing 51 includes a thermal insulator 51a, which contains the ceiling and encloses the entire processing container 10, and a reinforcement 51b, which reinforces the thermal insulator 51a at the outer periphery of the thermal insulator 51a. The thermal insulator 51a is made mainly of, for example, silica, alumina, or others, and serves to prevent heat transfer. The reinforcement 51b is made of a metal such as stainless steel. Further, to minimize the impact of heat on the outside of the temperature regulation furnace 50, the outer periphery of the reinforcement 51b is covered with a water cooling jacket (not illustrated).

The external heater 52 of the temperature regulation furnace 50 may be configured appropriately to heat the plurality of substrates W within the processing container 10. For example, an infrared heater that radiates infrared rays to heat the processing container 10 may be used as the external heater 52. In this case, the external heater 52 is formed in a wire shape, and is held on an inner peripheral surface of the thermal insulator 51a via a holder (not illustrated) to have a spiral, annular, arc, shank, or meandering shape.

Furthermore, the temperature regulation furnace 50 includes a cooler 60 that circulates a cooling gas such as air into the temperature regulation space 53 in order to cool the processing container 10 during or after film formation. The cooler 60 includes an external supply path 61 and flow rate adjuster 62, which are provided outside the temperature regulation furnace 50, a supply flow path 63 formed in the reinforcement 51b, and a supply hole 64 formed in the thermal insulator 51a.

The external supply path 61 is connected to a blower (not illustrated) and is branched at an intermediate position into a plurality of branch paths 61a. The flow rate adjuster 62 is provided for each of the plurality of branch paths 61a to adjust the flow rate of air circulating through each branch path 61a. A plurality of supply flow paths 63 are arranged along the axial direction (vertical direction) of the reinforcement 51b and extend respectively in an annular shape along the circumferential direction. A plurality of supply holes 64 are arranged horizontally at the same axial position as the respective supply flow paths 63 to blow out the air introduced into the respective supply flow paths 63 toward the temperature regulation space 53.

Further, the cooler 60 includes an exhaust hole 65 in the ceiling of the housing 51 for discharging the air supplied into the temperature regulation space 53. The exhaust hole 65 is connected to an external exhaust path 66 provided at the outside of the housing 51.

The controller 90 of the substrate processing apparatus 1 may utilize a computer having a processor 91, a memory 92, and an input/output interface (not illustrated). The processor 91 is one or combinations of a central processing unit (CPU), graphics processing unit (GPU), application specific integrated circuit (ASIC), field-programmable gate array (FPGA), a circuit including a plurality of discrete semiconductors, and others. The memory 92 is a combination of a volatile memory and a non-volatile memory (e.g., compact disk, digital versatile disc (DVD), hard disk, flash memory, etc.) as appropriate.

The memory 92 stores programs to operate the substrate processing apparatus 1 and recipes containing process conditions for substrate processing. The controller 90 reads and executes the programs and recipes from the memory 92 using the processor 91, thereby executing the substrate processing in the substrate processing apparatus 1. The controller 90 may be configured by a host computer or a plurality of client computers that communicate information through a network.

In substrate processing, the controller 90 interlocks the temperature regulation furnace 50 and the internal heater 70 to heat each substrate W, and also controls the supply of gases through the gas supply 30 as well as the exhaust of gases through the gas exhauster 40.

### [Substrate Processing Method]

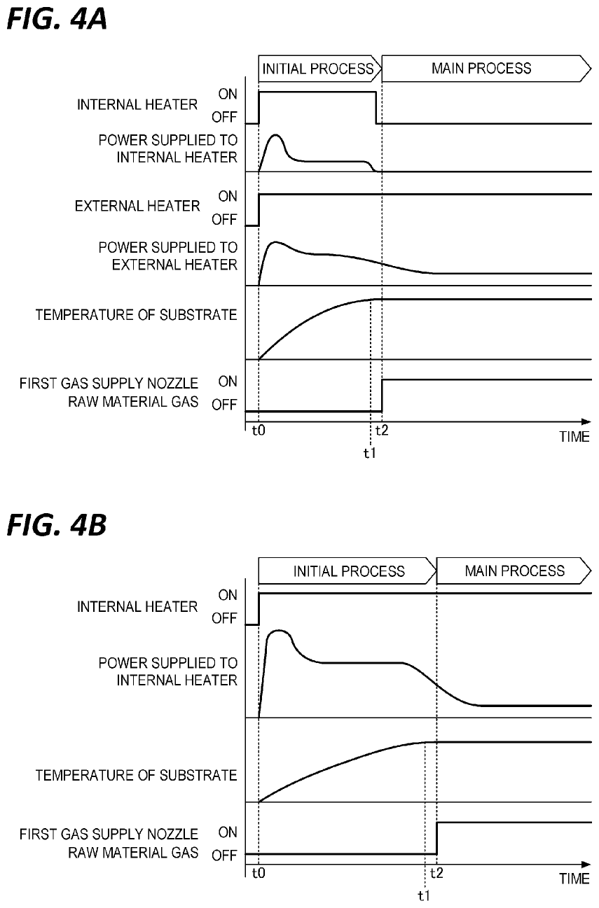

FIG. 4A is a timing chart illustrating a substrate processing method of the substrate processing apparatus 1 according to the embodiment. FIG. 4B is a timing chart illustrating a substrate processing method of a substrate processing apparatus according to a reference example. As illustrated in FIGS. 4A and 4B, after inserting the wafer boat 16 into the processing container 10 to accommodate each substrate W, the controller 90 sequentially executes an initial process and a main process as substrate processing.

The initial process involves heating the inside of the processing container 10 (each substrate W) before supplying the processing gases (raw material gas and reaction gas) to reach a target temperature during substrate processing. Further, in the initial process, the substrate processing apparatus 1 maintains a constant internal pressure of the processing container 10 through the supply of the purge gas into the processing container 10 as well as the discharge of the gases from the processing container 10 using the gas exhauster 40. The controller 90 also maintains the constant internal pressure of the processing container 10 in the main process by controlling both the gas supply 30 and the gas exhauster 40.

The controller 90 monitors the temperature within the processing container 10 using the temperature sensor, and transitions from the initial process to the main process once the temperature becomes stable at the target temperature. The main process involves sequentially supplying the raw material gas and reaction gas, thereby forming a desired film on the surface of the substrate W. At this time, the controller 90 maintains the temperature within the processing container 10 (temperature of each substrate W) at the target temperature. In the main process, the controller 90 may supply the purge gas together with the raw material gas or the reaction gas, or may supply the purge gas between the supply of the raw material gas and the supply of the reaction gas, or after supply of the reaction gas.

Hereinafter, to compare with the substrate processing method of the substrate processing apparatus 1 according to the embodiment illustrated in FIG. 4A, first, a substrate processing apparatus according to a reference example illustrated in FIG. 4B will be described. The substrate processing apparatus according to the reference example differs from the substrate processing apparatus 1 according to the embodiment in that it does not include the internal heater 70 within processing container 10. Other configurations of the substrate processing apparatus according to the reference example are the same as those in the substrate processing apparatus 1 according to the embodiment.

In this case, the substrate processing apparatus according to the reference example heats each substrate W within the processing container 10 through the heating of the external heater 52 of the temperature regulation furnace 50. Since heating is performed at the outside of the outer cylinder 12, the substrate processing apparatus according to the reference example needs to supply a significant amount of electrical power to the external heater 52 in the initial process to heat the processing container 10 and each substrate W.

In detail, after the start of the initial process, the controller 90 turns on the external heater 52 of the temperature regulation furnace 50 to output electrical power to the external heater 52. At this time, the controller 90 outputs a significant amount of power supplied to the external heater 52 in order to reach a target temperature of each substrate W. In particular, the controller 90 supplies a large transient power after the start of the initial process at time to to rapidly increase the temperature of the external heater 52 itself. Then, after supplying the transient power, the controller 90 continues to output a significant amount of power until the temperature of the entire processing container 10 is raised. This allows each substrate W to be gradually raised in temperature by receiving heat radiation from the outside of the processing container 10.

Then, at time t1 after the lapse of a certain period from time to, the temperature of each substrate W reaches the target temperature. When the controller 90 recognizes that the temperature of each substrate W has reached the target temperature, the controller 90 terminates the initial process at time t2 and transitions to the main process. At this time, the controller 90 operates the gas supply 30 to supply the raw material gas into the processing container 10 from the first gas supply nozzle 31A. This allows the raw material gas to adhere well to the surface of each temperature-regulated substrate W.

Further, the controller 90 may reduce the amount of power supplied to the temperature regulation furnace 50 in the main process. This is because in this main process stage, to maintain the temperature of each substrate W at the target temperature, heating is only performed to compensate for factors such as heat dissipation to the outside of the temperature regulation furnace 50 and a temperature decrease due to gas supply.

In the above substrate processing apparatus according to the reference example, the implementation duration of the initial process until reaching the main process becomes long, and the amount of power supplied for heating in the initial process becomes substantial. In particular, it is necessary to supply a significant amount of power to the external heater 52 at the start of the initial process in order to rapidly raise the temperature of each substrate W within a short period.

In contrast, as illustrated in FIG. 4A, the substrate processing apparatus 1 according to the embodiment turns on each internal heater 70 and also turns on the external heater 52 of the temperature regulation furnace 50 at the start of the initial process. This allows the substrate processing apparatus 1 to heat each substrate W from the inside of the processing container 10 and to heat the processing container 10 from the outside of the processing container 10. In particular, each internal heater 70 may rapidly raise the temperature of each substrate W by heating each substrate W from a position sufficiently close to the substrate W.

In detail, after the start of the initial process (time t0), the controller 90 outputs the power supplied to each internal heater 70 and also outputs the power supplied to the external heater 52 of the temperature regulation furnace 50. At this time, by heating each substrate W using each internal heater 70, the controller 90 may reduce the amount of power to the external heater 52, compared to the amount of power to the external heater 52 according to the reference example. Further, each internal heater 70, which performs heating using the heater wire 72 extending in the vertical direction inside the processing container 10, has a smaller heating range than the external heater 52 enclosing the entire processing container 10, making it possible to be set to a low amount of power. In other words, the substrate processing apparatus 1 may significantly reduce the amount of power during the initial process, which is the sum of the amount of power to each internal heater 70 and the amount of power to the external heater 52, compared to the amount of power during the initial process of the substrate processing apparatus according to the reference example.

By interlocking the external heater 52 and each internal heater 70 to perform heating in this way, the substrate processing apparatus 1 may significantly shorten the period (period from time t0 to time t1) of raising the temperature of each substrate W, compared to the period in the substrate processing apparatus according to the reference example. Therefore, the substrate processing apparatus 1 may transition from the initial process to the main process within a short period. Then, before transitioning to the main process at time t2, the substrate processing apparatus 1 reduces the amount of power to the internal heater 70 and turns off the internal heater 70. Then, at time t2, the substrate processing apparatus 1 operates the gas supply 30 to supply the raw material gas into the processing container 10 from the first gas supply nozzle 31A. This allows the raw material gas to adhere well to the surface of each temperature-regulated substrate W.

In particular, in the main process, heating is only required to maintain the temperature of each substrate W at the target temperature, and by turning off each internal heater 70 and continuing heating with the external heater 52, which may result in a significant reduction in power consumption. Further, in the main process, turning off each internal heater 70 may prevent unevenness in the in-plane temperature distribution of the substrate W caused by heat applied to each substrate W from each internal heater 70. In FIG. 4A, the supply of the raw material gas is initiated (turned on) at specific intervals after each internal heater 70 is turned off. This allows for a more uniform in-plane temperature distribution of the substrate W before substrate processing.

As described above, the substrate processing apparatus 1 may smoothly raise the temperature of each substrate W within the processing container 10 by interlocking the external heater 52 and each internal heater 70. As a result, the substrate processing apparatus 1 may rapidly raise the temperature of each substrate W stored in the inside of the processing container 10 within a short period while reducing the power consumption during heating.

The substrate processing apparatus 1 and the substrate processing method are not limited to the above-described embodiment and may take various modifications. For example, in the above example, the substrate processing apparatus that supplies the raw material gas and reaction gas to each substrate W to form a desired film on the surface of each substrate W has been described. However, the substrate processing apparatus 1 is not limited to this, and may be configured as an etching apparatus for etching a film formed on the surface of each substrate W. In this case, the substrate processing apparatus 1 may include components to generate a plasma within the processing container 10.

Further, the substrate processing apparatus 1 is not limited to heating using the internal heater 70 only in the initial process and may also employ heating using the internal heater 70 in the main process. For example, the substrate processing apparatus 1 may perform heating at a first temperature in the initial process and then heating at a second temperature lower than the first temperature in the main process. This may further promote the uniformity of the in-plane temperature distribution of each substrate W during substrate processing.

Furthermore, the substrate processing apparatus 1 may have a configuration where a plurality of zones are set along the vertical direction for the internal heater 70 and the temperature of the heater wire 72 installed in each of the plurality of zones may be independently adjusted. For example, the internal heater 70 may be controlled to raise the temperature of a specific zone corresponding to one of the plurality of substrates W arranged in the vertical direction that is prone to temperature decrease (e.g., the substrate W near the bottom in proximity to the thermal-insulating structure 27), while lowering the temperature of other zones.

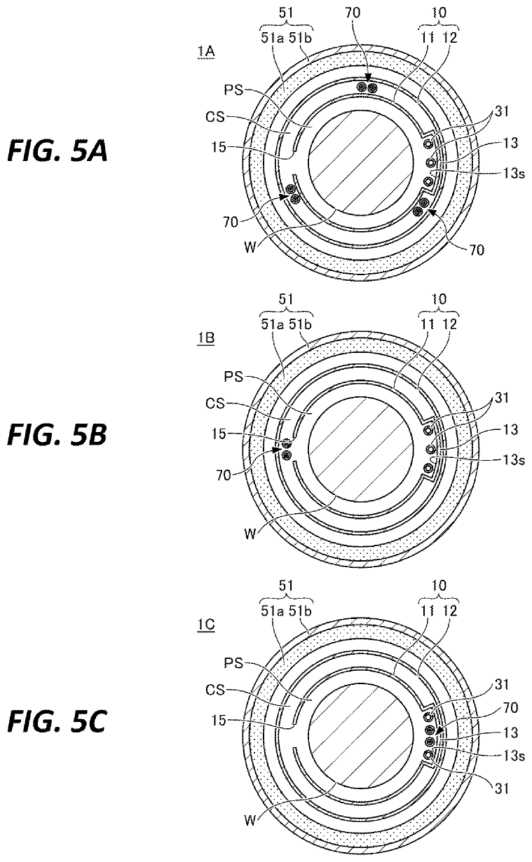

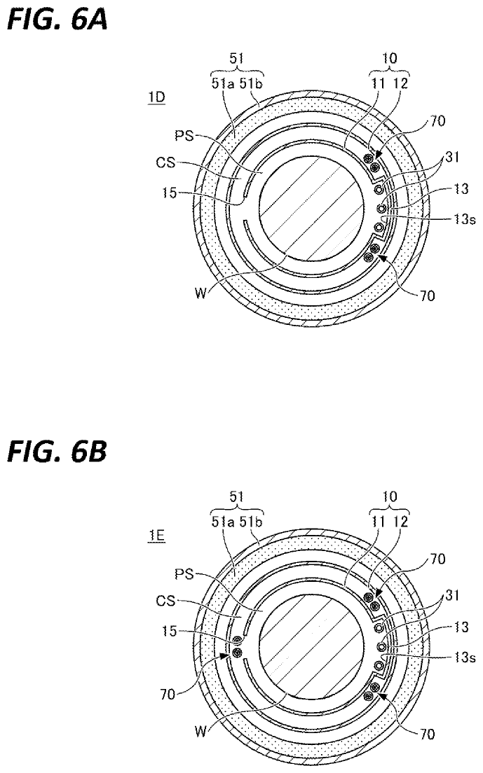

Further, the substrate processing apparatus 1 is not particularly limited in terms of the installation form of the internal heater 70 within the processing container 10 and may employ various patterns. Hereinafter, several other examples of the installation form of the internal heater 70 will be given with reference to FIGS. 5A to 6B. FIG. 5A is a cross-sectional view illustrating the installation form of the internal heater 70 according to a first modification. FIG. 5B is a cross-sectional view illustrating the installation form of the internal heater 70 according to a second modification. FIG. 5C is a cross-sectional view illustrating the installation form of the internal heater 70 according to a third modification. FIG. 6A is a cross-sectional view illustrating the installation form of the internal heater 70 according to a fourth modification. FIG. 6B is a cross-sectional view illustrating the installation form of the internal heater 70 according to a fifth modification.

A substrate processing apparatus 1A according to the first modification illustrated in FIG. 5A differs from the substrate processing apparatus 1 according to the embodiment in that the plurality of (three) internal heaters 70 are provided between the inner cylinder 11 and the outer cylinder 12 (in the circulation space CS). The configuration other than the internal heater 70 is the same as that of the substrate processing apparatus 1 according to the embodiment, and a detailed description thereof is omitted (the same is applied to the following modifications). Each internal heater 70 heats each substrate W from the circulation space CS. Although this configuration makes it more difficult to heat the substrate W compared to the configuration where each internal heater 70 is positioned within the inner cylinder 11, it is possible to prevent particles from being generated by the raw material gas or reaction gas coming into contact with each internal heater 70 within the inner cylinder 11, and these particles from adhering to each substrate W.

A substrate processing apparatus 1B according to the second modification illustrated in FIG. 5B differs from the above substrate processing apparatuses 1 and 1A in that a single internal heater 70 is provided outside the inner cylinder 11 at a position facing the opening 15 (in the circulation space CS). By positioning the single internal heater 70 at the opening 15 in this way, it is possible to efficiently heat each substrate W with a reduced impact of the inner cylinder 11. Moreover, since the internal heater 70 is positioned near the opening 15 through which the raw material gas or reaction gas flows out, any particles generated by the internal heater 70 may be prevented from reaching the processing space PS, which may prevent the particles from adhering to each substrate W.

A substrate processing apparatus 1C according to the third modification illustrated in FIG. 5C differs from the above substrate processing apparatuses 1, 1A and 1B in that a single internal heater 70 is provided in the nozzle accommodating space 13s inside the nozzle protrusion 13. By providing the internal heater 70 in the nozzle accommodating space 13s in this way, the internal heater 70 may heat a location that is prone to temperature decrease due to gas supply. For example, the substrate processing apparatus 1C may heat the processing gases circulating within the gas supply nozzle 31 through the heating of the internal heater 70 in the main process.

A substrate processing apparatus 1D according to the fourth modification illustrated in FIG. 6A differs from the above-described substrate processing apparatuses 1 and 1A to 1C in that a plurality of (two) internal heaters 70 are positioned between the inner cylinder 11 and adjacent to the nozzle protrusion 13. By positioning the internal heaters 70 outside the inner cylinder 11 and adjacent to the nozzle protrusion 13 in this way, each internal heater 70 may efficiently heat a location that is prone to temperature decrease due to gas supply.

A substrate processing apparatus 1E according to the fifth modification illustrated in FIG. 6B differs from the above-described substrate processing apparatuses 1 and 1A to 1D in that two internal heaters 70 are positioned between the inner cylinder 11 and the outer cylinder 12 and adjacent to the nozzle protrusion 13 and a single internal heater 70 is positioned at a position facing the opening 15. This allows the substrate processing apparatus 1E to heat a location that is prone to temperature decrease due to gas supply with each internal heater 70 and to directly heat the substrate W from the opening 15.

### SUMMARY

The technical ideas and effects of the present disclosure described in the above embodiments will be described below.

A first aspect of the present disclosure relates to a substrate processing apparatus 1; 1A to 1E including a processing container 10 that accommodates a plurality of substrates W in an inside thereof to perform a substrate processing on the plurality of substrates W, a gas supply nozzle 31 that supplies a gas to the inside of the processing container 10, and an external heater 52 that heats the plurality of substrates W from an outside of the processing container 10, in which the substrate processing apparatus further includes an internal heater 70 that is provided independently of the gas supply nozzle 31 in the inside of the processing container 10 and extends at a lateral side of the plurality of substrates W in a direction in which the plurality of substrates W are arranged to heat the plurality of substrates W.

According to the above, the substrate processing apparatus 1; 1A to 1E may efficiently raise the temperature of the plurality of substrates W accommodated in the inside of the processing container 10 by interlocking the external heater 52 and the internal heater 70. This allows the substrate processing apparatus 1; 1A to 1E to start the main process of supplying the processing gas at an earlier stage. Moreover, by using the internal heater 70, the substrate processing apparatus 1; 1A to 1E may reduce the amount of power supplied to the external heater 52. As a result, the substrate processing apparatus 1 may significantly reduce the power consumption during heating.

Further, the processing container 10 includes an inner cylinder 11 having a first space (processing space PS) that accommodates the plurality of substrates W and an outer cylinder 12 that accommodates the inner cylinder 11 to form a second space (circulation space CS) between the inner cylinder 11 and the outer cylinder 12, and the inner cylinder 11 includes a nozzle protrusion 13 that protrudes radially outward from a portion of a circumferential direction to accommodate the gas supply nozzle 31 therein and an opening 15 that is provided at a position opposite to the nozzle protrusion 13 across an axis of the inner cylinder 11 to provide communication between the first space and the second space. This allows the substrate processing apparatus 1; 1A to 1E to smoothly supply the processing gas from the gas supply nozzle 31 to the plurality of substrates W accommodated in the inner cylinder 11, while also allowing the discharge of the processing gas from the opening 15, thereby facilitating effective substrate processing.

Further, the internal heater 70 is provided inside the inner cylinder 11. This allows the substrate processing apparatus 1; 1C to raise the temperature of each substrate W even more rapidly with the internal heater 70.

Further, the inner cylinder 11 includes a heater protrusion 14 that protrudes radially outward at a circumferential position different from the nozzle protrusion 13, and the internal heater 70 is accommodated inside the heater protrusion 14. This allows the substrate processing apparatus 1 to heat each substrate W with the internal heater 70 while preventing the internal heater 70 from coming into direct contact with each substrate W even when the internal heater 70 is provided inside the inner cylinder 11.

Further, the internal heater 70 is provided in the second space (circulation space CS) between the inner cylinder 11 and the outer cylinder 12. This allows the substrate processing apparatus 1A; 1B; 1D; 1E to prevent particles from adhering to the substrate W even when the particles are generated by the internal heater 70.

Further, the internal heater 70 is provided at a position facing the opening 15 in the second space (circulation space CS). This allows the substrate processing apparatus 1B; 1E to smoothly heat the plurality of substrates W through the opening 15 even when the internal heater 70 is provided in the second space without heating from the inner cylinder 11.

Further, the internal heater 70 is provided at a position adjacent to the nozzle protrusion 13 along a circumferential direction of the processing container 10. This allows the substrate processing apparatus 1; 1A; 1D; 1E to raise the temperature of a location that is probe to temperature decrease due to gas supply from the gas supply nozzle 31 through the heating of the internal heater 70.

Further, the internal heater 70 is provided inside the nozzle protrusion 13. This allows the substrate processing apparatus 1C to heat the periphery of the gas supply nozzle 31 more effectively.

Further, the substrate processing apparatus includes a controller 90 that controls the external heater 52 and the internal heater 70, and the controller 90 controls a process including: (A) raising a temperature of the plurality of substrates W through heating of the external heater 52 and heating of the internal heater 70 in a state where supply of a processing gas from the gas supply nozzle 31 is stopped at a start of the substrate processing; and (B), after (A), supplying the processing gas from the gas supply nozzle 31 while stopping the heating of the internal heater 70 and continuing the heating of the external heater 52. This allows the substrate processing apparatus 1; 1A to 1E to efficiently raise the temperature of each substrate W at the start of substrate processing, while stabilizing the substrate processing with the processing gas by no longer heating each substrate W after the temperature rise.

Further, the controller 90 lowers an amount of power supplied to the external heater 52 in (B), compared to an amount of power supplied to the external heater 52 in (A). This allows the substrate processing apparatus 1; 1A to 1C to restrict the power consumption in (B), resulting in a significant reduction in the overall power consumption during substrate processing.

Further, the internal heater 70 includes a tubular member 71 made of quartz and a heater wire 72 accommodated in an inside of the tubular member 71. This allows the substrate processing apparatus 1 to easily install the internal heater 70 within the processing container 10.

Further, a second aspect of the present disclosure relates to a substrate processing method including providing a substrate processing apparatus 1 including a processing container 10 that accommodates a plurality of substrates W in an inside thereof to perform a substrate processing on the plurality of substrates W, a gas supply nozzle 31 that supplies a gas to the inside of the processing container 10, and an external heater 52 that heats the plurality of substrates W from an outside of the processing container 10; and heating the plurality of substrates W by an internal heater 70 that is provided independently of the gas supply nozzle 31 in the inside of the processing container 10 and extends at a lateral side of the plurality of substrates W in a direction in which the plurality of substrates W are arranged. In this case, the substrate processing method may efficiently raise the temperature of the plurality of substrates W accommodated in the inside of the processing container 10 while reducing the power consumption during heating.

According to an aspect, it is possible to efficiently raise the temperature of a plurality of substrates accommodated in the inside of a processing container while reducing the power consumption during heating.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container configured to accommodate a plurality of substrates in an inside thereof to perform a substrate processing on the plurality of substrates;
a gas supply nozzle configured to supply a gas to the inside of the processing container; and
an external heater configured to heat the plurality of substrates from an outside of the processing container,
wherein the substrate processing apparatus further comprises an internal heater provided independently of the gas supply nozzle in the inside of the processing container and extending at a lateral side of the plurality of substrates in a direction in which the plurality of substrates are arranged to heat the plurality of substrates.

2. The substrate processing apparatus according to claim 1, wherein the processing container includes an inner cylinder having a first space that accommodates the plurality of substrates and an outer cylinder that accommodates the inner cylinder to form a second space between the inner cylinder and the outer cylinder, and
wherein the inner cylinder includes:
a nozzle protrusion that protrudes radially outward from a portion of a circumferential direction to accommodate the gas supply nozzle therein; and
an opening provided at a position opposite to the nozzle protrusion across an axis of the inner cylinder to provide communication between the first space and the second space.

3. The substrate processing apparatus according to claim 2, wherein the internal heater is provided inside the inner cylinder.

4. The substrate processing apparatus according to claim 3, wherein the inner cylinder includes a heater protrusion that protrudes radially outward at a circumferential position different from the nozzle protrusion, and
the internal heater is accommodated inside the heater protrusion.

5. The substrate processing apparatus according to claim 2, wherein the internal heater is provided in the second space between the inner cylinder and the outer cylinder.

6. The substrate processing apparatus according to claim 5, wherein the internal heater is provided at a position facing the opening in the second space.

7. The substrate processing apparatus according to claim 2, wherein the internal heater is provided at a position adjacent to the nozzle protrusion along a circumferential direction of the processing container.

8. The substrate processing apparatus according to claim 2, wherein the internal heater is provided inside the nozzle protrusion.

9. The substrate processing apparatus according to claim 1, further comprising:
a controller configured to control the external heater and the internal heater,
wherein the controller controls a process including:
(A) raising a temperature of the plurality of substrates through heating of the external heater and heating of the internal heater in a state where supply of a processing gas from the gas supply nozzle is stopped at a start of the substrate processing; and
(B), after (A), supplying the processing gas from the gas supply nozzle while stopping the heating of the internal heater and continuing the heating of the external heater.

10. The substrate processing apparatus according to claim 9, wherein the controller lowers an amount of power supplied to the external heater in (B), compared to an amount of power supplied to the external heater in (A).

11. The substrate processing apparatus according to claim 1, wherein the internal heater includes:
a tube made of quartz; and
a heater wire accommodated in an inside of the tube.

12. A substrate processing method comprising:
providing a substrate processing apparatus including:
a processing container that accommodates a plurality of substrates in an inside thereof to perform a substrate processing on the plurality of substrates;
a gas supply nozzle that supplies a gas to the inside of the processing container; and
an external heater that heats the plurality of substrates from an outside of the processing container; and
heating the plurality of substrates with an internal heater provided independently of the gas supply nozzle in the inside of the processing container and extending at a lateral side of the plurality of substrates in a direction in which the plurality of substrates are arranged.
